(19) United States
(12) Patent Application Publication
(10) Pub. No.: US 2021/0336014 A1
(43) Pub. Date: Oct. 28, 2021

(54) SEMICONDUCTOR DEVICE AND METHOD FOR MANUFACTURING SAME

(71) Applicant: CHANGXIN MEMORY TECHNOLOGIES, INC., Hefei (CN)

(72) Inventor: Yanjie ZHANG, Hefei (CN)

(73) Assignee: CHANGXIN MEMORY TECHNOLOGIES, INC., Hefei (CN)

(21) Appl. No.: 17/371,079

(22) Filed: Jul. 8, 2021

Related U.S. Application Data
(63) Continuation of application No. PCT/CN2021/078514, filed on Mar. 1, 2021.

(30) Foreign Application Priority Data
Mar. 9, 2020 (CN) 202010157194.1

(51) Int. Cl. H01L 29/40; H01L 29/423; H01L 29/66; H01L 29/78; H01L 21/28

(52) U.S. Cl. CPC H01L 29/401; H01L 29/42364; H01L 21/28044; H01L 29/7833; H01L 29/6659

(57) ABSTRACT

A method for manufacturing a semiconductor device includes: providing a semiconductor substrate; sequentially forming stacked layers of a gate oxide layer and a gate polysilicon layer on the semiconductor substrate; performing fluorine ion implantation at a predetermined temperature after forming the gate polysilicon layer, and annealing after the ion implantation to form Si—F bonds at an interface between the gate oxide layer and the semiconductor substrate; in which the predetermined temperature is between −100° C. and −10° C.

### CROSS-REFERENCE TO RELATED APPLICATIONS

The present application is a continuation of International Application No. PCT/CN2021/078514 filed on Mar. 1, 2021, which claims priority to Chinese Patent Application No. 202010157194.1 filed on Mar. 9, 2020. The disclosures of these applications are hereby incorporated by reference in their entirety.

### BACKGROUND

Negative bias temperature instability (NBTI) effect is a common phenomenon that occurs in PMOS devices, which causes instability in device parameters such as threshold voltage, saturation current and transconductance when the PMOS devices are operated under a gate negative bias voltage and a high temperature. As the size of a semiconductor is miniaturized, the gate electric field of the semiconductor structure increases and the operating temperature of the integrated circuit increases, which leads to more serious NBTI effect that results in the deterioration of the device performances.

### SUMMARY

The present disclosure relates generally to the technical field of semiconductors, and more specifically to a semiconductor device and a method for manufacturing the same.

An object of embodiments of the disclosure is to provide a semiconductor device and a method for manufacturing the same, so as to reduce the negative bias instability effect of the semiconductor device and improve the reliability of the same.

Various embodiments of the disclosure provide a method for manufacturing a semiconductor device, which includes the steps of: providing a semiconductor substrate, sequentially forming stacked layers of a gate oxide layer and a gate polysilicon layer on the semiconductor substrate, performing fluorine ion implantation at a predetermined temperature after forming the gate polysilicon layer, and annealing after the ion implantation to form Si—F bonds at an interface between the gate oxide layer and the semiconductor substrate, in which the predetermined temperature is between −100° C. and −10° C.

Examples of the disclosure further provide a semiconductor device, which is manufactured by the method of manufacturing a semiconductor device described above.

The semiconductor structure of embodiments of the disclosure is subjected to the fluorine ion implantation process at the low temperature so as to repair the unbonded dangling bonds at the interface between the gate oxide layer and the semiconductor substrate, and form the Si—F bonds with higher energy, thereby greatly reducing the NBTI effect. In addition, the crystal lattice is in a lower energy state and the atoms are relatively inactive under the low temperature condition. In this condition, the fluorine ion implantation under such condition reduces the damage to the crystal lattice caused by the implantation, which results in fewer end-to-range defects, thereby reducing the electric leakage phenomenon and improving the yield and reliability of the semiconductor device.

In some embodiments, the forming of the stacked layers of the gate oxide layer and the gate polysilicon layer includes: sequentially forming stacked layers of an initial oxide layer and an initial polysilicon layer on a first surface of the semiconductor substrate, and etching the initial oxide layer and the initial polysilicon layer to form a patterned gate oxide layer and a patterned gate polysilicon layer.

In some embodiments, the method further includes: before performing the fluorine ion implantation process at the low temperature, before performing the fluorine ion implantation at the predetermined temperature, forming a first mask layer on the first surface of the semiconductor substrate covering the exposed first surface of the semiconductor substrate; and after performing the fluorine ion implantation at the predetermined temperature, removing the first mask layer. The first mask layer covering the exposed first surface of the semiconductor substrate is formed to cover source and drain regions on the semiconductor substrate, to prevent the crystal lattice of the source and drain regions from being damaged by the implanted fluorine ions and to avoid influence on subsequent ion doping of the source and drain regions.

In some embodiments, the first mask layer is a photoresist. The photoresist is used as the first mask layer for protecting the semiconductor substrate, which is easily formed and removed, and the process difficulty and the cost for manufacturing the semiconductor device can be reduced.

In some embodiments, performing the fluorine ion implantation at the predetermined temperature specifically includes: performing the fluorine ion implantation via the gate polysilicon layer in a vertical direction.

In some embodiments, the method further includes: before performing the fluorine ion implantation at the predetermined temperature, forming dielectric layer sidewalls adjacent to the gate oxide layer and the gate polysilicon layer, and forming lightly doped drains on the semiconductor substrate at both sides of the gate oxide layer; performing the fluorine ion implantation at the predetermined temperature specifically includes: performing an inclined fluorine ion implantation through the lightly doped drains at an inclined angle.

In some embodiments, the method further includes: before performing the fluorine ion implantation at the predetermined temperature, and after forming the dielectric layer sidewalls, forming a second mask layer located above the gate polysilicon layer away from the semiconductor substrate; and after performing the fluorine ion implantation at the predetermined temperature, removing the second mask layer.

In some embodiments, performing the fluorine ion implantation at the predetermined temperature specifically includes: implanting a fluorine ion source at a direction that forms an angle θ with the first surface and the angle θ is between 30° and 90°. By selecting an appropriate fluorine ion implantation angle according to the gate size, it is possible to accurately control the fluorine ion implanted to a target position to obtain a high quality amorphous layer and reduce the influence to the fluorine ion on the source doped region and the drain doped region, thereby improving the stability and extending the service life of the semiconductor device.

In some embodiments, the fluorine ion source used for performing the fluorine ion implantation at the predetermined temperature includes boron fluoride gas.

In some embodiments, an implantation energy used for performing the fluorine ion implantation at the predetermined temperature is 0.5 KeV˜15 KeV, and an implantation dose is 5E11/cm²˜1E13/cm².

In some embodiments, an annealing temperature is between 900° C. and 1100° C. If the annealing temperature is too high, the implanted fluorine ions will diffuse rapidly, thereby resulting in leakage of the fluorine ions. However, if the annealing temperature is too low, the repair of the ion damage is poor, and the formation rate of the Si—F bonds at the interface between the gate oxide layer and the semiconductor substrate is low, which results in unsatisfied improvement of the reduction of the negative bias instability effect. With the above mentioned annealing temperature, the drawbacks can be avoided, thus stable Si—F bonds at the interface between the gate oxide layer and the semiconductor substrate are formed, thereby improving the negative bias voltage instability effect of the semiconductor.

### BRIEF DESCRIPTION OF THE DRAWINGS

FIG. 1 is a first schematic structural diagram corresponding to steps of the method for manufacturing a semiconductor device according to an embodiment of the disclosure.

FIG. 2 is second schematic structural diagram corresponding to steps of the method for manufacturing a semiconductor device according to an embodiment of the disclosure.

FIG. 3 is third schematic structural diagram corresponding to steps of the method for manufacturing a semiconductor device according to an embodiment of the disclosure.

FIG. 4 is first schematic structural diagram corresponding to steps of the method for manufacturing a semiconductor device according to another embodiment of the disclosure.

FIG. 5 is a second schematic structural diagram corresponding to steps of the method for manufacturing a semiconductor device according to another embodiment of the disclosure.

### DETAILED DESCRIPTION

In order to make the objects, technical solutions and advantages of the embodiments of the disclosure more clearly, the embodiments of the disclosure will be described in detail with reference to the accompanying drawings. However, it will be appreciated by those skilled in the art that in various embodiments of the disclosure numerous technical details are set forth in order to enable readers to better understand the disclosure. However, the technical solution as claimed in the disclosure can be realized without these technical details and various changes and modifications based on the following embodiments. The following embodiments are divided for the convenience of description and should not be construed as limiting any particular implementation of the disclosure, and the embodiments may be incorporated with reference to each other as long as no conflict therebetween.

The formation of the Si—SiO₂ interface state of a gate oxide layer can be a main factor leading to the NBTI effect. During operation of the device, a negative voltage forms a high electric field on the gate, and the Si—H bond formed by annealing in the H₂ atmosphere is easily broken, thereby forming the interface state and traps trapped positive charges, thereby causing the NBTI effect of the integrated circuit device. In the related art, by fluorine ion doping in an interface region of the gate oxide layer, the unbonded dangling bonds are repaired and Si—F bonds with higher energy which are more difficult to be broken than the Si—H bonds are formed. At the same time, the introduction of fluorine can suppress defects caused by boron which is doped in source/drain tunneling the gate oxide layer, thereby reducing the NBTI effect.

To greatly reduce the NBTI effect to improve the reliability of the semiconductor device, a fluorine ion doping process can be improved.

The first embodiment of the disclosure provides a method for manufacturing a semiconductor device, which includes the steps of: providing a semiconductor substrate, sequentially forming stacked layers of a gate oxide layer and a gate polysilicon layer on the semiconductor substrate, performing fluorine ion implantation at a predetermined temperature after forming the gate polysilicon layer, and annealing after the ion implantation to form Si—F bonds at an interface between the gate oxide layer and the semiconductor substrate, in which the predetermined temperature is between −100° C. and −10° C.

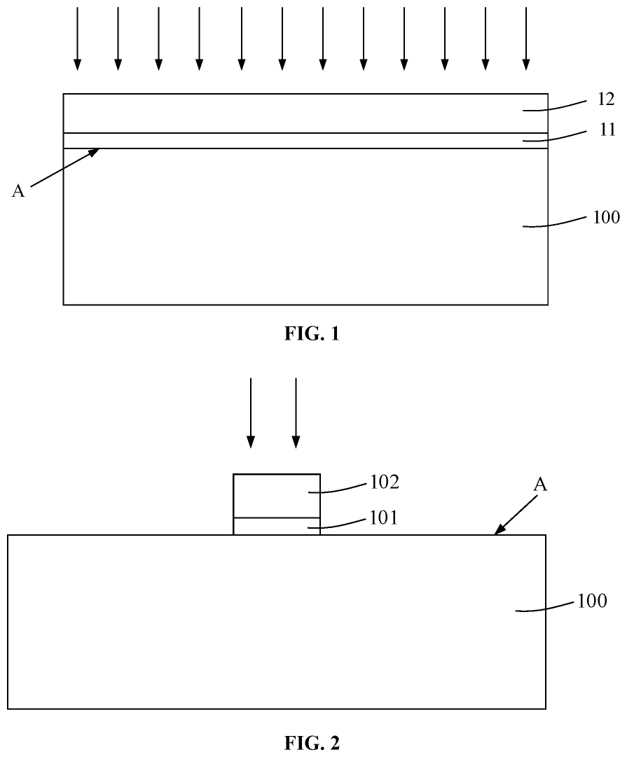

FIGS. 1 to 3 are schematic structural diagrams corresponding to the steps of the method for manufacturing a semiconductor device according to an embodiment of the disclosure, and the method for manufacturing a semiconductor device according to the embodiment will be described in detail below with reference to FIGS. 1 to 3.

S101. A semiconductor substrate 100 is provided.

Referring to FIG. 1, the material of the semiconductor substrate 100 in the embodiment is silicon. In other embodiments, the material of the semiconductor substrate may be silicon-on-insulator (SOI), germanium, silicon germanium, or gallium arsenide or the like. Several epitaxial interface layers or strain layers may be formed on the surface of the semiconductor substrate 100 to improve the electrical performance of the semiconductor device.

An isolation structure (not shown) may also be formed in the semiconductor substrate 100. The conventional isolation structure generally employs a shallow trench isolation structure. The filling material of the shallow trench isolation structure may be one or a mixture of two or more selected from silicon oxide, silicon nitride and silicon oxynitride. The shallow trench isolation structure is primarily used for isolating the first region (not shown) and the second region (not shown) to prevent electrical connections between different semiconductor devices.

S102. Stacked layers of the gate oxide layer 101 and the gate polysilicon layer 102 are sequentially formed on the semiconductor substrate 100.

Further referring to FIG. 1, on the first surface A of the semiconductor substrate 100, sequentially forming an initial oxide layer 11 and an initial polysilicon layer 12 which is on the surface of the initial oxide layer 11 away from the semiconductor substrate 100 by a deposition process. In the embodiment, the stacked layers of the initial silicon oxide layer 11 and the initial polysilicon layer 12 sequentially formed on the first surface A of the semiconductor substrate 100 may use the method of the low-pressure chemical vapor deposition (LPCVD), the plasma enhanced chemical vapor deposition (PECVD), the thermal oxidation process or the in-situ steam generation (ISSG).

In the process of forming the initial oxide layer 11 with the in-situ steam generation, the reaction gases H₂ and O₂ are directly reacted with the silicon material on the surface of the semiconductor substrate 100 to form the initial oxide layer 11. During the reaction, a large number of gas phase reactive radicals having oxidation properties are generated, including reactive oxygen atoms, water molecules, OH groups and the like. Since the reactive oxygen atoms have a very strong oxidation effect, defects of the initial oxide layer 11 are decreased, and trapped charges and interface states at the interface between the semiconductor substrate 100 and the initial oxide layer 11 are reduced. Therefore, the issue of the negative bias voltage instability of the semiconductor device can be improved.

In the process of forming the initial oxide layer with the thermal oxidation process, the silicon substrate may be oxidized at a temperature between 800° C. and 1000° C. in an oxygen/steam atmosphere. With the thermal oxidation process the initial oxide layer and the silicon substrate are closely contact with each other, thus have good interfacial properties therebetween, thereby preventing the generation of interfacial defects.

In the PECVD process, the substrate is generally kept at about 350° C. to obtain a good SiO film, at which the deposition rate is high, and the film forming quality is good.

In other embodiments, the initial oxide layer and the initial polysilicon layer may be formed by other deposition processes, and the formation process for the initial oxide layer and the initial polysilicon layer is not specifically limited herein.

Referring to FIG. 2, an initial oxide layer 11 and an initial polysilicon layer 12 are etched to form a patterned gate oxide layer 101 and a patterned gate polysilicon layer 102. The material of the gate oxide layer 101 in the embodiment is silicon oxide. In other embodiments, the material of the gate oxide layer may also be SiON, a stack of SiO and SiON, or other high-K dielectric material. Among them, the high-K dielectric material refers to a material whose relative dielectric constant is greater than that of silicon oxide. For example, the high-K dielectric material may be HfSiO, HfO₂, HfSiON, HfTaO, HfSiO, HfZrO, ZrO₂ or Al₂O₃.

Specifically, a patterned mask layer (not shown) defining the gate electrode is formed on the surface of the initial polysilicon layer 12 away from the semiconductor substrate 100, the initial oxide layer 11 and the initial polysilicon layer 12 are etched by a dry or wet etching process to form the gate oxide layer 101 and the gate polysilicon layer 102, and the patterned mask layer on the surface of the gate polysilicon layer 102 is removed after the etching process is completed. In other embodiments, the initial polysilicon layer may be removed by a dry or wet etch process and the initial oxide layer may be retained, or the patterned gate oxide layer and gate polysilicon layer may be formed directly on the first surface of the semiconductor substrate.

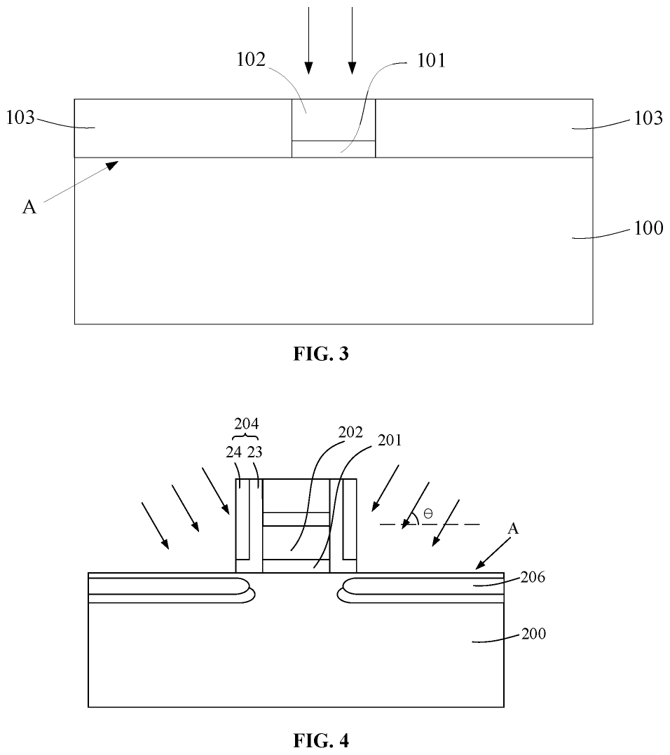

It should be noted that the fluorine ion implantation may damage the crystal lattice of the source and drain regions and affect the subsequent ion doping distribution in the source and drain regions. In order to avoid the subsequent influence to the source doped region (not identified) and the drain doped region (not identified) of the semiconductor substrate caused by the subsequent fluorine ion implantation process, referring to FIG. 3, in this embodiment, after the patterned gate oxide layer 101 and the patterned gate polysilicon layer 102 are formed, the method further includes the step in which a first mask layer 103 is formed on the first surface A of the semiconductor substrate 100, which covers the exposed first surface A of the semiconductor substrate 100.

The first surface area that exposes the semiconductor substrate 100 is the area on the first surface A of the semiconductor substrate 100 other than that occupied by the gate oxide layer 101, and the formed first mask layer 103 is closely adjacent to the sidewalls of the gate oxide layer 101 and the gate polysilicon layer 102. The first mask layer 103 covers the source doped region and the drain doped region on the semiconductor substrate 100, so that the influence of the fluorine ion doping process to the subsequent ion doping of the source and drain regions can be avoided.

It is understandable that forming the first mask layer 103 closely adjacent to the gate oxide layer 101 and the gate polysilicon layer 102 is not a necessary step of the embodiment. Referring to FIG. 2, in other embodiments, step S103 may also be performed after forming the patterned gate oxide layer 101 and gate polysilicon layer 102.

In the embodiment, material of the first mask layer 103 is a photoresist. By using the photoresist as the first mask layer 103, the formation process and the removal process are simple and inexpensive, and the cost for manufacturing the semiconductor device can be greatly reduced while protecting the semiconductor substrate 100 from being etched by fluorine ions. In other embodiments, other mask materials may also be used as the material of the first mask layer.

S103. The fluorine ion implantation is performed at a predetermined temperature, and the annealing is performed after the ion implantation to form Si—F bonds at the interface between the gate oxide layer 101 and the semiconductor substrate 100.

The predetermined temperature of the fluorine ion implantation process in the embodiment is between −100° C. and −100° C. The crystal lattice is in a lower energy state under the low temperature condition, and the atoms within the crystal lattice are relatively inactive, thus the crystal lattice is relatively less damaged during the fluorine ion implantation. Therefore, by performing fluoride ion implantation on the semiconductor structure at the low temperature, the damage to the crystal lattice caused by the ion implantation can be reduced, resulting in a fewer end-to-range defects, thereby reducing the electric leakage phenomenon and improving the yield of the semiconductor device.

In some embodiments, the temperature for the low temperature fluorine ion implantation process is −90° C., −80° C., −70° C., −60° C., −50° C., −40° C., −30° C. or −20° C. By performing fluorine ion implantation under the above-mentioned temperature condition, the stability of the negative bias voltage of the semiconductor device can be improved while the end-to-range defects can be further reduced, and thereby improving the yield of the semiconductor device.

It should be noted that in the embodiment, the fluorine ion implantation at a predetermined temperature specifically includes implanting a fluorine ion source through the gate polysilicon layer 102 in the vertical direction.

Referring to FIG. 3, the gate polysilicon layer 102 is subjected to a low temperature fluorine ion implantation in a direction perpendicular to the surface of the gate polysilicon layer 102, and the semiconductor structure obtained after the ion implantation is subjected to annealing, so that the gate oxide layer 101 is subjected to a low temperature fluorine ion implantation and the ion implanted gate oxide layer 101 is subjected to annealing. In this way, fluorine ions can diffuse to the gate oxide layer 101 via the gate polysilicon layer 102, and Si—F bonds are formed at the interface between the gate oxide layer 101 and the semiconductor substrate 100, thereby avoiding the instability of the semiconductor device in the case of a negative gate bias voltage or a high temperature.

Furthermore, with the low temperature fluorine ion implantation process, a flatter amorphous interface is formed in the gate polysilicon layer 102 and fewer end-to-range defects are generated, the surface damage to the surface of the semiconductor substrate 100 caused by the fluorine ions penetrating the gate polysilicon layer 102 and the gate oxide layer 101 onto the surface of the semiconductor substrate 100 is reduced, and the implanted fluorine ions have a relatively higher activation level and relatively less diffusion in the subsequent annealing process, thereby greatly reducing the NBTI effect and improving the reliability and the service life of the semiconductor device.

It is understandable that in other embodiments, the gate polysilicon layer may also be subjected to the low temperature fluorine ion implantation at a direction that forms an angle with the first surface.

In the embodiment, the fluorine ion source includes boron fluoride gas, and the implantation energy used for the fluorine ion implantation process at the predetermined temperature is 0.5 KeV˜15 KeV, and the implantation dose is 5E11/cm²˜1E13/cm². For example, the implantation energy is 1 KeV, 2 KeV, 3 KeV, 4 KeV, 5 KeV, 6 KeV, 7 KeV, 8 KeV, 9 KeV, 10 KeV, 11 KeV, 12 KeV, 13 KeV or 14 KeV, and the implantation dose is 6E11/cm², 8E11/cm², 1E12/cm², 2E12/cm², 4E12/cm², 5E12/cm², 6E12/cm² or 8E12/cm².

It should be noted that in the embodiment, only the combinations of the implantation energy and implantation doses that result in a superior ion implantation effect is exemplified. In other embodiments, other values of implantation energy and implantation doses may be used. In addition, in other embodiments, the fluorine ion source may also be HF solution or the like.

The annealing process in the embodiment employs a high temperature rapid annealing process at a temperature between 900° C. and 1100° C. For example, the annealing temperature is 950° C., 1000° C. or 1050° C. If the annealing temperature is too high, the implanted fluorine ions will diffuse rapidly, thereby resulting in leakage of the fluorine ions. However, if the annealing temperature is too low, the damage by the ions cannot be well repaired, and the formation rate of the Si—F bonds at the interface between the gate oxide layer and the semiconductor substrate is low, which leads to unsatisfied effect in the improvement for the negative bias instability effect of the semiconductor device. With the above mentioned annealing temperature, the drawbacks can be avoided, therefore stable Si—F bonds at the interface between the gate oxide layer and the semiconductor substrate can be formed, thereby reducing the negative bias voltage instability effect of the semiconductor.

It should be noted that since the photoresist is not resistant to high temperature, in this embodiment, the first mask layer 103 on the semiconductor substrate 100 is removed before the annealing process. Specifically, the first mask layer 103 is removed by a wet etching process. For example, the photoresist as the material of the first mask layer 103 is removed by etching with a mixed solution of sulfuric acid and hydrogen peroxide as the etching liquid, followed by a washing treatment with a mixed solution of ammonia and hydrogen peroxide.

In other embodiments, the first mask layer may also be made of other commonly used mask layer materials, in which the first mask layer may be removed by etching or the like after the annealing process.

In other embodiments, referring to FIG. 1, before forming the patterned gate oxide layer 101 and the patterned gate polysilicon layer 102, a fluorine ion source may be implanted into the initial polysilicon layer 12 in a direction perpendicular to the initial polysilicon layer 12, and the initial oxide layer 11 and the initial polysilicon layer 12 are etched after the low temperature fluorine ion implantation process to form the patterned gate oxide layer 101 and gate polysilicon layer 102, and the ion implanted gate oxide layer 101 and gate polysilicon layer 102 are annealed to diffuse the fluorine ions from the gate polysilicon layer 102 to the gate oxide layer 101, and Si—F bonds are formed at the interface between the semiconductor substrate 100 and the gate oxide layer 101.

After the annealing process is performed on the gate oxide layer 101 after the fluorine ion implantation, the gate metal layer and the insulating dielectric layer are further formed on the semiconductor substrate 100, and the source doped region and the drain doped region are respectively formed on the sides of the gate oxide layer 101.

According to the method for manufacturing a semiconductor device of this embodiment, the fluorine ion implantation process is performed on the semiconductor structure at a low temperature to repair unbonded dangling bonds at the interface between the gate oxide layer and the semiconductor substrate, thereby greatly reducing the NBTI effect. In addition, the crystal lattice is in a lower energy state under the low temperature condition, and the atoms are relatively inactive. The fluorine ion implantation is performed under such condition that the damage to the crystal lattice caused by the ion implantation can be reduced, which results in fewer end-to-range defects, thereby reducing the electric leakage phenomenon and improving the yield and reliability of the semiconductor device.

An additional embodiment of the disclosure relates to a method for manufacturing a semiconductor device. The additional embodiment is substantially the same as the above example, and the main difference lies in that before performing the fluorine ion implantation at a low temperature, the method further includes: forming dielectric layer sidewalls closely adjacent to the gate oxide layer and the gate polysilicon layer, and forming lightly doped drains on the semiconductor substrate at both sides of the gate oxide layer, the fluorine ion implantation at the predetermined temperature specifically includes: performing an inclined fluorine ion implantation via the lightly doped drains.

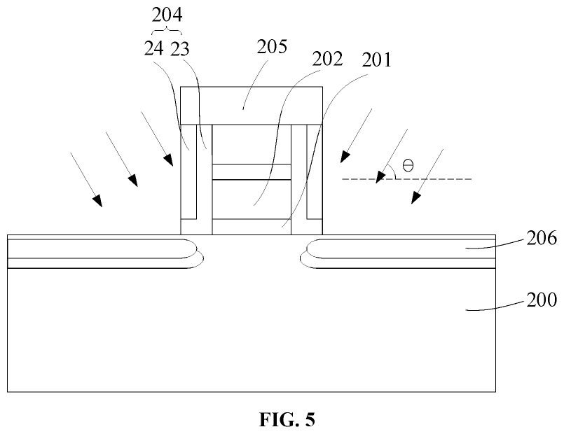

FIGS. 4 and 5 are schematic structural diagrams corresponding to the steps of the method of manufacturing a semiconductor device according to the additional embodiment of the disclosure. The details that are same as or similar to those in the above-described embodiments can be referred to the previous embodiments, and these details are not described again.

S201. A semiconductor substrate 200 is provided.

S202. Stacked layers of the gate oxide layer 201 and the gate polysilicon layer 202 are sequentially formed on the semiconductor substrate 200.

S203. Dielectric layer sidewalls 204 closely adjacent to the gate oxide layer 201 and the gate polysilicon layer 202 are formed, and lightly doped drains 206 are formed on the semiconductor substrate 200 at the both sides of the gate oxide layer 201.

Referring to FIG. 4, the dielectric layer sidewalls 204 of the embodiment include the first dielectric layer sidewalls 23 and the second dielectric layer sidewalls 24. The material of the first dielectric layer sidewalls 23 is silicon nitride and the material of the second dielectric layer sidewalls 24 is silicon oxide. In other embodiments, the material of the first dielectric layer sidewalls may also be other high-K dielectric materials.

It is understandable that in the embodiment, a gate metal layer (not identified) and an insulating dielectric layer (not identified) on the surface of the gate polysilicon layer 202 away from the semiconductor substrate 200 are also formed before forming the dielectric layer sidewalls 204, and the gate oxide layer 201, the gate polysilicon layer 202, the gate metal layer and the insulating dielectric layer are stacked in sequence to form a gate structure, and the dielectric layer sidewalls 204 are located on the both sides of the gate structure.

Specifically, forming the dielectric layer sidewalls 204 closely adjacent to the gate structure includes depositing a silicon nitride layer and a silicon oxide layer covering the surface of the formed semiconductor structure in sequence by using the atomic deposition process or the chemical vapor deposition process both having good step coverage after forming the gate structure. The formed silicon oxide layer and silicon nitride layer are etched by a dry etching process having an alignment etching effect so as to remove the silicon oxide layer and the silicon nitride layer that cover the first surface A of the semiconductor substrate 200 and the insulating dielectric layer after etching, and only the silicon nitride layers and the silicon oxide layers on the sides of the gate structure are left to form the first dielectric layer sidewalls 23 and the second dielectric layer sidewalls 24.

In order to form the doped source/drain regions on the semiconductor substrate 200, the Halo doped region is formed on the semiconductor substrate 200 by an N-type Halo doping process after forming the dielectric layer sidewalls 204, and P-type lightly doped drain 206 are formed on the semiconductor substrate 200 at both sides of the gate oxide layer 201 after forming the N-type Halo doping process.

A Lightly Doped Drain (LDD) structure is a structure adopted by the MOSFET in order to reduce an electric field of the drain to improve a hot carrier injection effect. That is, a low-doped drain region is provided in the channel close to a drain so that the low-doped drain region also bears a partial voltage, and therefore such structure can prevent the hot carrier injection effect. The hot carrier effect is an important failure principle of the MOS (metal-oxide-semiconductor) devices. The hot carrier injection effect of the MOS devices becomes more and more serious as the size of the devices is increasingly reduced. Taking the PMOS devices as an example, the holes in the channel are accelerated by a high lateral electric field between the source and the drain to form high energy carriers, which collide with the silicon lattices to generate the ionized electron -hole pairs, in which electrons are collected by the substrate to form a substrate current, and most of the holes generated by the collision flow to the drain, whereas a part of the holes are injected into the gate under the longitudinal electric field to form the gate current, which is referred to as the hot carrier injection.

Hot carriers can cause breakage of bond energy at the interface between the silicon substrate and the gate oxide layer, which causes the interface state at the interface between the silicon substrate and the gate oxide layer, resulting in deterioration of device properties, such as threshold voltage, transconductance and linear/saturation region current, and finally resulting in the failure of the MOS device. The failure usually occurs at the drain firstly, because the energy of the carriers reaches the maximum value when they arrive at the drain after being accelerated by the electric field of the entire channel, so that the hot carrier injection phenomenon at the drain is relatively serious.

As the device size enters the sub-micron channel length range, the electric field strength inside the device increases with the reduction of the device size. In particular there is a strong electric field in the vicinity of the drain, in which the carriers obtain high energy and become hot carriers. The hot carriers affect the properties of a device in two aspects. On one hand, the hot carriers cross the Si—SiO₂ barrier and inject into the oxide layer and accumulate to change the threshold voltage, and thereby affecting the service life; on the other hand, the hot carriers in the depletion region near the drain collide with the crystal lattices to produce electron-hole pairs. For the NMOS transistor, an additional leakage current is formed for the electrons produced by the collision, and the holes are collected by the substrate to form a substrate current, so that the total current becomes the sum of the saturated leakage current and the substrate current. The greater the substrate current is, the greater the number of collisions occurs in the channel, and the corresponding hot carrier effect is more serious. The hot carrier effect is one of the basic factors limiting the maximum operating voltage of the device.

It should be noted that in order to avoid the subsequent influence of the low temperature fluorine ion implantation process to the gate structure, referring to FIG. 5, the embodiment further includes the step in which a second mask layer 205 is formed on the gate polysilicon layer 202 away from the semiconductor substrate 200 after the formation of the dielectric layer sidewalls 204. The second mask layer 205 in this embodiment is a photoresist.

S204, under a predetermined temperature, the inclined fluorine ion implantation is performed through the P-type lightly doped drain 206, and annealing is performed after the fluorine ion implantation to form Si—F bonds at the interface between the gate oxide layer 201 and the semiconductor substrate 200.

In the embodiment, the fluorine ion implantation at a predetermined temperature specifically includes implanting a fluorine ion source at a direction that forms an angle θ with the first surface A. The angle θ is between 30° and 90°. For example, the inclined angle θ is 40°, 50°, 60°, 70° or 80°.

Specifically, the angle for the fluorine ion implantation is related to the size of the gate structure. A suitable fluorine ion implantation angle is selected according to the gate size, and the low temperature fluorine ion implantation on the gate oxide layer 201 is performed through the semiconductor substrate 200 regions surrounding the gate oxide layer 201, so that a high quality amorphous layer can be obtained by accurately controlling the fluorine ion being implanted to a target position, and the influence of the fluorine ion to the source doped region and the drain doped region can be reduced, thereby improving the stability and the service life of the semiconductor device.

After the fluorine ion implantation process at the predetermined temperature, the photoresist layer located above the gate polysilicon layer 202 away from the semiconductor substrate 200 is removed and the device is subjected to annealing by a high temperature rapid annealing process.

With respect to the related art, in the method for manufacturing a semiconductor device of some embodiments disclosed herein, the interface area of the gate oxide layer 201 is doped with fluorine ions by the fluorine ion implantation at a low temperature through the region of the semiconductor substrate 200 surrounding the gate oxide layer 201, so as to repair the unbonded dangling bonds at the interface between the gate oxide layer and the semiconductor substrate, and form the Si—F bonds which have a higher energy, thereby greatly reducing the NBTI effect. In addition, the crystal lattice is in a lower energy state under the low temperature, and the atoms are relatively inactive. Under this condition, the fluorine ion implantation can reduce the damage to the crystal lattices caused by the ion implantation, and result in fewer end-to-range end defects, thereby reducing the electric leakage phenomenon and improving the yield and reliability of the semiconductor device.

Accordingly, a further embodiment of the disclosure provides a semiconductor device, which is manufactured by the method of manufacturing a semiconductor device described above

The semiconductor device in the embodiment is, such as the PMOS transistor, the logic circuit, the dynamic random-access memory or the like.

It will be understood by the ordinary skilled person in the art that the above-described embodiments are specific examples for realizing the disclosure, and that various changes may be made in form and detail in practical applications without departing from the spirit and scope of the disclosure. Any person skilled in the art may make respective changes and modifications without departing from the spirit and scope of the disclosure, and therefore the protection scopes of the disclosure are the scopes defined by the claims.

What is claimed is:

1. A method for manufacturing a semiconductor device, comprising:
providing a semiconductor substrate;
sequentially forming stacked layers of a gate oxide layer and a gate polysilicon layer on the semiconductor substrate; and
performing fluorine ion implantation at a predetermined temperature after forming the gate polysilicon layer, and annealing after the ion implantation to form Si—F bonds at an interface between the gate oxide layer and the semiconductor substrate;
wherein the predetermined temperature is between −100° C. and −100° C.

2. The method for manufacturing a semiconductor device according to claim 1, wherein said sequentially forming the stacked layers of the gate oxide layer and the gate polysilicon layer comprises:
sequentially forming stacked layers of an initial oxide layer and an initial polysilicon layer on a first surface of the semiconductor substrate; and
etching the initial oxide layer and the initial polysilicon layer to form a patterned gate oxide layer and a patterned gate polysilicon layer.

3. The method for manufacturing a semiconductor device according to claim 2, further comprising:
prior to said performing the fluorine ion implantation at the predetermined temperature, forming a first mask layer on the first surface of the semiconductor substrate covering the exposed first surface of the semiconductor substrate; and
after said performing the fluorine ion implantation at the predetermined temperature, removing the first mask layer.

4. The method for manufacturing a semiconductor device according to claim 3, wherein the first mask layer is a photoresist.

5. The method for manufacturing a semiconductor device according to claim 3, wherein said performing fluorine ion implantation at the predetermined temperature further comprises performing the fluorine ion implantation via the gate polysilicon layer in a vertical direction.

6. The method for manufacturing a semiconductor device according to claim 1, further comprising:
prior to said performing the fluorine ion implantation at the predetermined temperature, forming dielectric layer sidewalls adjacent to the gate oxide layer and the gate polysilicon layer, and forming lightly doped drains on the semiconductor substrate at both sides of the gate oxide layer; and performing the fluorine ion implantation at the predetermined temperature specifically comprises performing an inclined fluorine ion implantation through the lightly doped drains.

7. The method for manufacturing a semiconductor device according to claim 6, further comprising: prior to said performing the fluorine ion implantation at the predetermined temperature and after forming the dielectric layer sidewalls, forming a second mask layer located above the gate polysilicon layer away from the semiconductor substrate; and after said performing the fluorine ion implantation at the predetermined temperature, removing the second mask layer.

8. The method for manufacturing a semiconductor device according to claim 6, wherein said performing the fluorine ion implantation at the predetermined temperature further comprises:
implanting a fluorine ion source at a direction that forms an angle θ with the first surface, wherein the angle θ is between 30° and 90°.

9. The method for manufacturing a semiconductor device according to claim 1, wherein the fluorine ion source used for the fluorine ion implantation at the predetermined temperature comprises boron fluoride gas.

10. The method for manufacturing a semiconductor device according to claim 1, wherein an implantation energy used for the fluorine ion implantation at the predetermined temperature is 0.5 KeV˜15 KeV, and an implantation dose is 5E11/cm²˜1E13/cm².

11. The method for manufacturing a semiconductor device according to claim 1, wherein an annealing temperature is between 900° C. and 1100° C.

12. A semiconductor device manufactured with the method for manufacturing a semiconductor device according to claim 1.

13. A semiconductor device manufactured with the method for manufacturing a semiconductor device according to claim 2.

14. A semiconductor device manufactured with the method for manufacturing a semiconductor device according to claim 3.

15. A semiconductor device manufactured with the method for manufacturing a semiconductor device according to claim 5.

16. A semiconductor device manufactured with the method for manufacturing a semiconductor device according to claim 6.

17. A semiconductor device manufactured with the method for manufacturing a semiconductor device according to claim 8.

18. A semiconductor device manufactured with the method for manufacturing a semiconductor device according to claim 10.

19. A semiconductor device manufactured with the method for manufacturing a semiconductor device according to claim 7.

20. A semiconductor device manufactured with the method for manufacturing a semiconductor device according to claim 11.
